(19) United States
(12) Patent Application Publication
(10) Pub. No.: US 2008/0011814 A1
(43) Pub. Date: Jan. 17, 2008

(54) Method and System for Self-Aligning Parts in Mems

(75) Inventors: Stefano Oggioni, Milano (IT); Thomas Albrecht, San Jose, CA (US); Michel Despont, Au (IT); Mark Lantz, Adliswil (CH); Michele Castriotta, Manfredonia (IT)

Correspondence Address: INTERNATIONAL BUSINESS MACHINES CORPORATION;DEPT. 18G, BLDG. 300-482, 2070 ROUTE 52, HOPEWELL JUNCTION, NY, 12533, US

(73) Assignee: INTERNATIONAL BUSINESS MACHINES CORPORATION, Armonk, NY (US)

(21) Appl. No.: 10/596,349

(22) PCT Filed: Nov. 8, 2004
(86) PCT No.: PCT/EP04/52846

§ 371 Date: Jun. 9, 2006

(30) Foreign Application Priority Data
Dec. 19, 2003 (EP) 03368117.2

(51) Int. Cl. B23K 31/02; B81B 7/00

(52) U.S. Cl. 228/234.1; 228/245

(57) ABSTRACT

A method and system for efficiently self-aligning parts of a MEMS during manufacturing, as well as controlling distance between these parts, are disclosed. According to the invention each MEMS part comprises at least one pad that is aligned so as to form a pair of pads. In a preferred embodiment, each part comprises three pads. The pad shape of two pairs of pads is rectangular, one pair being rotated of an angle approximately equal to 90° from the other, and the pad shape of the third pair is annular. Therefore, one of the pair of pads allows alignment according to a first direction, a second pair of pads allows alignment according to a second direction, and the third pair of pads allows rotational alignment.

### FIELD OF THE INVENTION

The present invention relates generally to fabrication techniques and Micro-ElectroMechanical Systems (MEMS) and more specifically to a method and systems for self-aligning parts of the MEMS during manufacturing.

### BACKGROUND OF THE INVENTION

Micron-sized mechanical structures co-fabricated with electrical devices or circuitry using conventional Integrated Circuit (IC) methodologies are called micro-electromechanical systems or MEMS. There has been a great deal of recent interest in the development of MEMS devices for applications such as projection devices, displays, sensors and data storage devices. For example, one of IBM's projects concerning data storage device demonstrates a data density of a trillion bits per square inch, 20 times higher than the densest magnetic storage currently available. The device uses thousands of nanometer-sharp tips to punch indentations representing individual bits into a thin plastic film. The result is akin to a nanotech version of the data processing ‘punch card’ developed more than 110 years ago, but with two crucial differences: the used technology is re-writeable (meaning it can be used over and over again), and may be able to store more than 3 billion bits of data in the space occupied by just one hole in a standard punch card.

The core of the device is a two-dimensional array of v-shaped silicon cantilevers that are 0.5 micrometers thick and 70 micrometers long. At the end of each cantilever is a downward-pointing tip less than 2 micrometers long. The current experimental setup contains a 3 mm by 3 mm array of 1,024 (32×32) cantilevers, which are created by silicon surface micro-machining. A sophisticated design ensures accurate leveling of the tip array with respect to the storage medium and dampens vibrations and external impulses. Time-multiplexed electronics, similar to that used in DRAM chips, address each tip individually for parallel operation. Electromagnetic actuation precisely moves the storage medium beneath the array in both the x- and y-directions, enabling each tip to read and write within its own storage field of 100 micrometers on a side. The short distances to be covered help ensure low power consumption.

FIG. 1 is a partial cross section view of the device (100). As shown, each cantilever 115 is mounted on a substrate 105 surmounted by a CMOS device 110, with a control structure 120, and comprises a downward-pointing tip 125 that is adapted to read or write (R/W) a bit on the surface of the storage scanner table 130. Thanks to electromagnetic actuator 135 storage scanner table 130 can move in at least one dimension as illustrated by arrows. The part comprising the storage scanner table 130, the actuator 135 and the support structure 140 must be precisely aligned on the CMOS device 110, at a predetermined distance. CMOS device 110 has all the required electronics to control required functions such as R/W operations. In this implementation example, alignment functional targets in X and Y axis are on the order of ±10 μm (micrometer), while the functional gap between the storage scanner table 150 and the CMOS device 110 that works also as a supporting plate for the R/W cantilevers has a maximum distance of 6 μm with sub-micron tolerance.

The combination of electrical and mechanical features associated with the required part alignment accuracy leads to the use of dedicated manufacturing tools that directly impacts device cost. In the high volume production of this kind of product for the consumer market such investments would become very high due to an intrinsic conflict between throughput (capacity) and precision alignment requirements. Therefore, there is a need for a method and systems for aligning efficiently parts of the MEMS during manufacturing, without requiring dedicated and complex manufacturing tools.

### SUMMARY OF THE INVENTION

Thus, it is a broad object of the invention to remedy the shortcomings of the prior art as described here above.

It is another object of the invention to provide a method and systems for efficiently self-aligning parts of the MEMS during manufacturing, according to X and Y directions.

It is a further object of the invention to provide a method and systems for efficiently self-aligning parts of the MEMS during manufacturing, according to rotational misalignment.

It is still a further object of the invention to provide a method and systems for efficiently self-aligning parts of the MEMS during manufacturing while controlling the distance between these parts.

The accomplishment of these and other related objects is achieved by a method for precisely aligning at least two parts of an electronic device, each part of the electronic device comprising at least one pad, the at least one pad of a first of the at least two parts being aligned with the at least one pad of a second of the at least two parts when the first and second parts are aligned, forming at least one pair of pads, the method comprising the steps of:

deposing glue on the at least one pad of a first part of the at least two parts,

aligning approximately the second part to the first part, and,

lying the second part on the first part.

These and other aspects of the invention are described in further detail below.

### BRIEF DESCRIPTION OF THE DRAWINGS

FIG. 1 is a partial cross section view of a device wherein the invention may be efficiently implemented.

FIG. 2, comprising FIGS. 2a and 2b, illustrates the concept of solder-reflow alignment process according to the invention.

FIG. 3, comprising FIGS. 3a and 3b, illustrates the concept of solder-reflow alignment process combined with mechanical spacers.

FIG. 4 is a partial cross section view of the device of FIG. 1 wherein the invention is implemented.

FIG. 5, comprising FIGS. 5a, 5b, and 5c, shows a two-step approach for aligning parts of the MEMS and establishing a final Z spacing.

FIG. 6 illustrated a partial plan view of a device wherein the invention is implemented and shows the dominant force vectors based on each pad design.

FIGS. 7 and 8 show the shapes of the pads used for aligning MEMS parts according to the invention.

FIG. 9, comprising FIGS. 9a, 9b, 9c and 9d, shows an example of the control of the pad sizes and the alloy volumes.

FIGS. 10 and 11 show examples of apparatus used to implement the invention when Z force is applied in a manner which does not upset the previously established in-plane alignment.

FIG. 12 depicts two examples of arrangements that can be used in conjunction with the invention to determine when the required Z position of MEMS parts is reached.

### DETAILED DESCRIPTION OF THE INVENTION

According to the invention there is provided a design strategy allowing stacking two or more parts of Micro-ElectroMechanical Systems (MEMS) with very high precise position via a solder-reflow process, which could also form a final electrical and/or mechanical connection between the parts of the MEMS. Furthermore the invention offers a self controlled correction of rotational placement errors and a self forced Z controlled height or functional standoff.

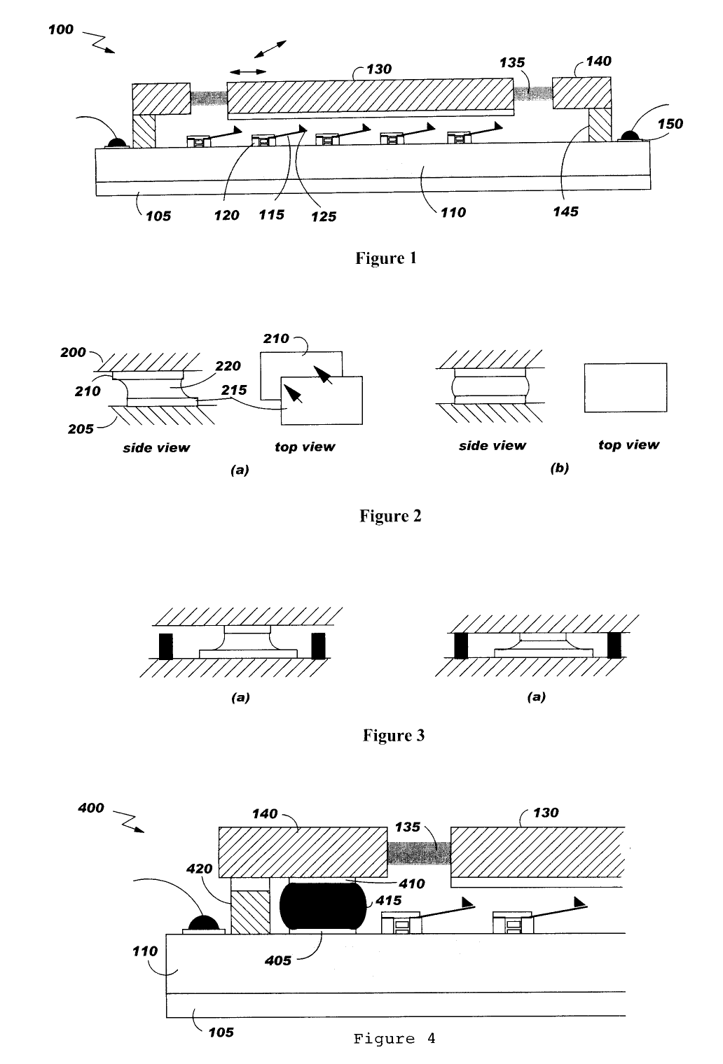

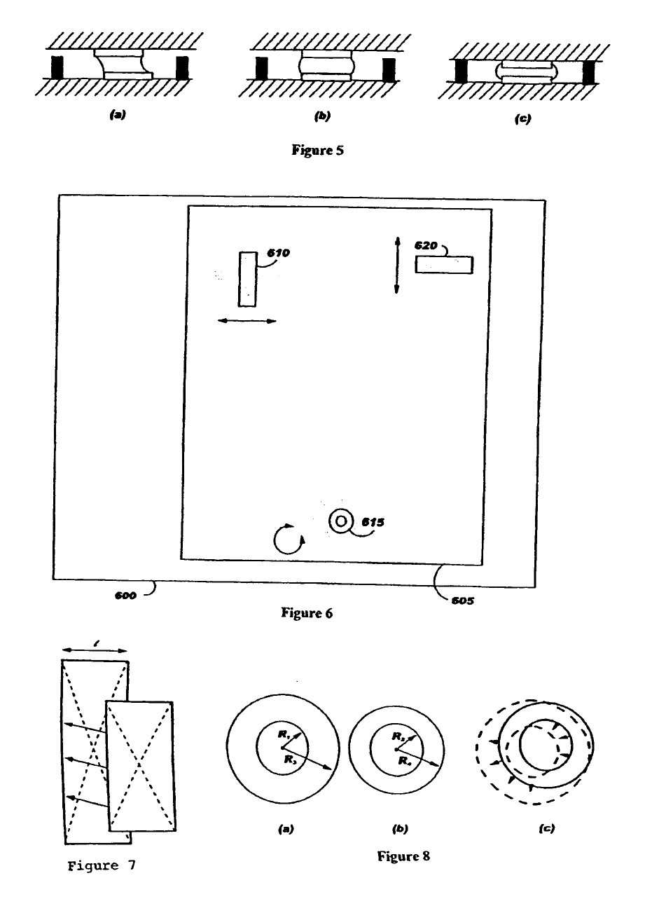

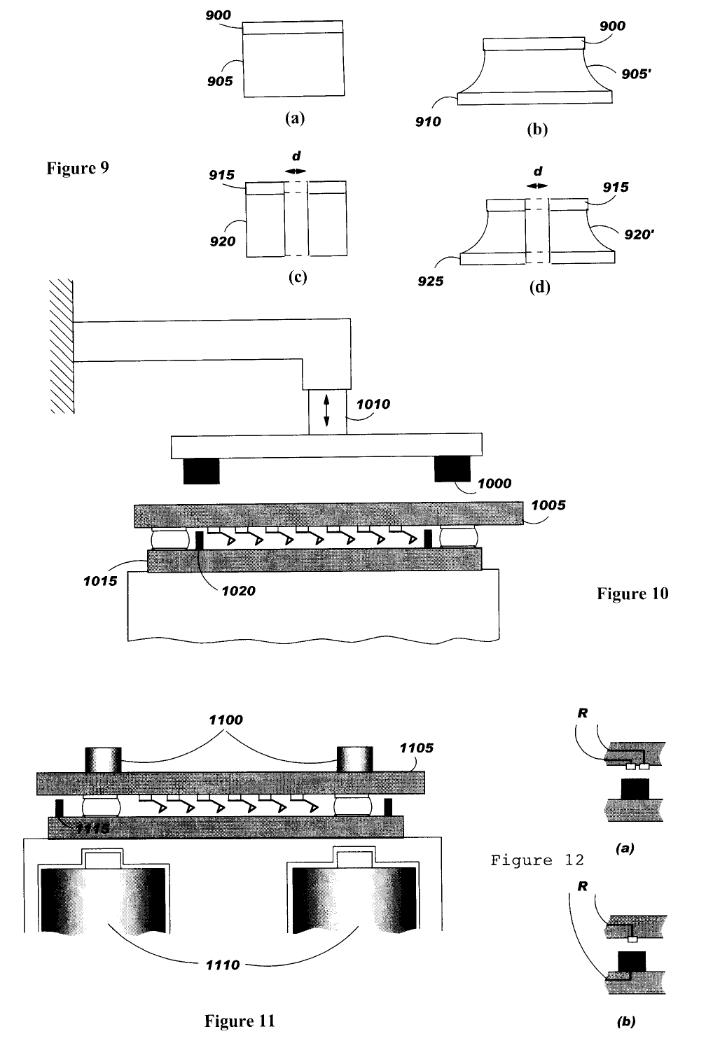

For sake of illustration, the description of the invention is based upon the example given above by reference to FIG. 1 concerning a data storage device. Such data storage device is made of a MEMS with a moving table, also referred to as a scanner or scanner table, and related electromagnetic controls, a CMOS device that has all the required electronics to control read and write (R/W) function performance and carrying a great number of single structures that are the R/W tips.

As mentioned above, there are precise functional requirements for the part stack-up. Alignment functional targets in X and Y axis are in the order of ±10 μm (micrometer), while the functional gap between the scanner table and the CMOS device that works also as a supporting plate for the R/W cantilevers has a maximum distance of 6 μm with sub-micron tolerance.

The solution addressed to solve the mechanical and functional requirements is to use self centering features using low cost industrial processes.

The implementation of specific design of metal pads and the utilization of selected soldering alloys such as standard eutectic Tin/Lead (63Sn/37Pb) or non eutectic Sn/Pb binary alloys such as Sn60/40Pb or 5Sn/95Pb, 10Sn/90Pb, 3Sn/97Pb or other “Lead-free” alloys such as Tin/Silver/Copper ternary alloys or other alloys that can be based on Indium or Silver, or Tin or other metals alloys allows taking advantage of the surface tension physics of the melted alloy deposit. Solder alloy can be selected based on the solder hierarchy required in the overall product manufacturing system and based on maximum acceptable temperature excursions that the different MEMS components can withstand to. The wetting phenomenon between the metal pads and the alloy in liquid phase drives the self centering operation along the X and Y axis between the two parts of the MEMS as illustrated on FIG. 2 that shows two parts (200, 205) of the MEMS, each comprising a pad (210, 215) in contact with alloy (220), at the beginning (a) and at the end (b) of the reflow process.

These tension effects in molten solder can also be used to create, when required in the same design, a complex system of forces for rotational self-alignment (theta axis) by creating moments to pivot around various features. Additionally, by adjusting the relative sizes of pads, controlled collapse in Z can be accomplished, bringing the structure against fixed stops to establish a precise Z spacing between parts of the MEMS devices. This process is shown on FIG. 3, with the state of the system at the beginning (a) and at the end (b) of the reflow process.

Without spacers present, the collapse will self-terminate at a height mainly determined by the pad shapes, the amount of solder, and the cooling process. For sub-micron Z height control, it is advantageous to have mechanical stops or spacers of precisely known height on the surface of one or both chips.

Various techniques are available to create these mechanical stops e.g., the same process used in bonding the levers to the CMOS chip can be used to create pillar structures which serve as precise spacers. In such case, the spacer is lithographically defined and is fabricated on at least one of the MEMS parts during their processing. Different method can be envisioned based on add-up technique, depositing and patterning of a layer of the proper spacer thickness (for example metal, polymer, oxide, etc.) or, by subtraction process, meaning recessing in the bulk material, by the proper thickness, the whole device area except the spacers e.g., by wet etching, plasma etching or sputter etching. The spacer can be also a discrete element that is deposited on the device surface before the joining.

FIG. 4 illustrates a device 400, wherein one embodiment of the invention is implemented, comprising two metal pads 405 and 410, linked by soldering alloy 415. In this implementation example, the distance between the CMOS device 110 and the part comprising the storage scanner table 130, the electromagnetic actuator 135, and the structure 140 is determined according to a spacer, or mechanical stop, 420.

According to the device shown on FIG. 4, the X, Y, and theta alignments can be performed, along with the Z collapse against spacers, in a single reflow step. An alternative method is to perform the in-plane alignments (X, Y, and theta) and the Z collapse as two separate steps. This alternative approach allows the use of identical pads on both surfaces (potentially saving real estate on the part surfaces) and also eliminates interaction between the two which might affect final position tolerances in certain applications.

As in the single-step process, passive spacers could also be used to ultimately set the final spacing in the two-step process. In such two-step process a switchable Z force drives the two MEMS parts together after in-plane alignment has occurred by a solder-reflow process. The Z force is applied in a manner which does not upset the previously established in-plane alignment. For sake of illustration, two types of apparatus, a plunger apparatus and a magnetic apparatus, are shown for accomplishing this two-step process in conjunction with solder-reflow heating apparatus by reference to FIGS. 10 and 11, respectively.

In the two-step approach, illustrated by reference to FIG. 5, the usual types of pad shapes, are provided to accomplish in-plane alignment. The amount of solder dispensed determines the state, FIG. 5b after in-plane alignment by reflow where the Z spacing between parts is greater than the height of the passive spacers. As a result, the spacers do not interfere with the in-plane alignment process, since there is no in-plane friction acting between the parts. After the in-plane alignment has been accomplished, and before the solder is allowed to cool and solidify, a vertical force is applied which pushes the parts together to a final position determined by the passive spacers, FIG. 5c.

Each pad design is inspired by the location and the resulting contribution of the same to the resulting forces that will drive the self alignment of the stacked MEMS parts. According to the invention, each MEMS part to be aligned comprises at least three pads, at least a portion of each pad of a part being exactly aligned to one pad of the other part when parts are precisely aligned.

In a preferred embodiment, there are three pads forming a triangle i.e., defining a plane, two of them being long rectangular pads, these have demonstrated to have a stronger pulling force along the direction orthogonal to the long side. These rectangular pads, being disposed according to an angle of approximately 90°, are responsible to give a consistent contribution to the X and Y macro-alignment but are responsible to achieve a precise micro-alignment (sub-micron level) of the metal pads and then of the MEMS parts. Making the pads rectangular and with a high aspect ratio between the two sides is also satisfying one of the requirements for the collapsing feature of the Z control process.

The third pad has to maintain the same X and Y recovering action (forces) but it can be at a lower level when it is basically centered but has the option of becoming a strong contributor to the self centering forces when the misplacement is at macro-level (tens of microns). The other main function of the latter pad design is to act as a pivotal point and to allow slight rotation of the system in association with the acting forces driven by the other two rectangular pads.

The definition of the design characteristics for the third pad resulted in a pad with a profile similar to a “Donut” where the resulting forces act along the pad as if the pad itself would be a long rectangular pad, with a high ratio between the two different edges, something very similar to the two remaining pads.

The melted alloy will wet the mating pads creating the aligning forces driving a complete and low surface energy 3D structure that can be reached only when an exact overlap of the wettable surfaces (pads) is present.

FIG. 6 illustrated a partial view of a device wherein the invention is implemented and shows the dominant forces vectors (arrows) based on each pad design. As illustrated, a MEMS part 600 comprises pads 610, 615 and 620 that are aligned to corresponding pads of another MEMS part 605, allowing the alignment of parts 600 and 605 during the solder-reflow process.

FIG. 7 depicts the corresponding pads of two MEMS parts i.e., a pair of pads, as well as the dominant forces allowing their alignment. As it is understandable from this drawing, both pads should have approximately the same widths l and different lengths so as to determine a main alignment direction. The greater misalignment distance that can be corrected is equal to approximately the half of the pad width i.e., l/2.

FIG. 8, comprising FIGS. 8a, 8b, and 8c, illustrates an example of pad design for the above discussed third pair of pads used as a pivotal point. In a preferred embodiment the internal radiuses R₁ and R₂ of the annular ring of both pads are equal, R₁=R₂, while the external radius of one of the pads is greater than the external radius of the second pad e.g., R₃>R₄. The greater misalignment distance that can be corrected is equal to approximately the half of the difference between the external radiuses of both pads i.e., (R₃−R₄)/2.

Therefore, the use of two similar pair of rectangular pads, one pair being rotated of an angle approximately equal to 90° from the other, and of an annular pair of pads as discussed above, allows an X and Y alignment as well as a rotational adjustment.

As it is mentioned above, a further embodiment of the self-centering pads allows also a controlled collapsing capability. In the given example, the specific MEMS stacking require a functional gap of 6 microns in between the two MEMS parts. To reliably achieve such a gap in a repetitive and constant way the metal pads can be designed having different wettable surface areas. The resulting combination of available volume of soldering alloy paired with the available wettable surfaces drives a distribution of the solder volume achieving a 3D structure with the minimum surface energy.

Once the required variables (volume and areas) have been set the MEMS parts will collapse one on top of the other to a point where equilibrium is reached, the resulting gap can be precisely determined with accurate sizing of the above mentioned variables.

Mechanical stops can also be used to achieve in a consistent way (batch to batch) the targeted functional gap in an industrial environment.

A further optimization of the Z control collapsing can be reached by underestimation of the required volume, at equilibrium, for a specific height and pads surfaces. This, with the addition of mechanical stops, of the precise targeted height, will create an over consumption of the alloy with a resulting collapsing action that would tend to reduce the gap beyond what is imposed by the presence of the mechanical stops. The result is a repetitive process that guaranties the required minimum gap with reduced dependencies on critical process variables tolerance that, in such small nominal dimensions (microns), may strongly influence the final result in this low tolerance tolerant system.

FIG. 9 and the following tables show an example of the different pad dimensioning based on the possible/available solder alloy volumes. Processes to deposit such small amount of soldering alloy do have different costs and different tolerance to the targeted volume. The tables were used to design targeted volumes with different surface areas based on steps of fixed solder deposits.

FIG. 9a illustrates a rectangular pad (900) configuration after solder (905) deposition and FIG. 9b shows the rectangular pads (900, 910) configuration after self-alignment operation and solder (905′) consumption. The geometrical configuration is then computed with good approximation to a pyramidal frustum with parallel faces.

Assuming that,

b is the area of the pad (900), on which alloy is deposited, that width and length are both equal to 100 μm,

B is the area of the receiving pad (910) that width is equal to 100 μm,

h is the height of alloy deposition, prior to joining and its value is a variable of solder deposition process capability for very small volumes. The value of h may be an independent variable that drives the overall sizing of the pads geometry,

H is the targeted height of alloy between pads (900, 910), and,

V is the alloy volume,

then,

$$V = H \cdot \frac{B + b + \sqrt{B \cdot b}}{3} \qquad ( 1 )$$

and the length of the receiving pad (910) is:

| | Height of alloy dep. h (μm) | | | | |
|---|---|---|---|---|---|
| | 15 | 14 | 13 | 12 | 10 |
| Receiving pad length (μm) | 560 | 510 | 460 | 410 | 320 |

Likewise, FIG. 9c illustrates an annular pad (915) configuration after solder (920) deposition and FIG. 9d shows the annular pads (915, 925) configuration after self-alignment operation and solder (920′) consumption. The geometrical configuration is then computed with good approximation to a conical frustum with parallel faces and a cylindrical cavity of volume

πR₁²H in the center.

Assuming that,

R₁ and R₂ are the radiuses of the empty circular areas in the center of both annular pads (915, 925), R₁ and R₂ are both equal to 50 μm,

R₄ is the external radius of the pad (915), on which alloy is deposited, it is equal to 150 μm,

R₃ is the external radius of the receiving pad (925)

h is the height of alloy deposition, prior to joining and its value is a variable of the capability of the solder deposition process for depositing very small volumes. The value of h may be an independent variable that drives the overall sizing of the pad geometry,

H is the targeted height of alloy between pads (915, 925), and,

V is the alloy volume,

then,

$$V = H π \cdot ( \frac{{R}_{3}^{2} + {R}_{3} {R}_{4} + {R}_{4}^{2}}{3} - {R}_{1}^{2} ) \qquad ( 2 )$$

and the external radius R₃ of the receiving pad (925) is:

| | Height of alloy dep. h (μm) | | | | |
|---|---|---|---|---|---|
| | 15 | 14 | 13 | 12 | 10 |
| Receiving pad radius (μm) | 340 | 325 | 310 | 290 | 260 |

For the alternative two-step process discussed above, which separates the in-plane alignment (X, Y, and theta) from the Z-collapse, two types of apparatus may be used to generate the switchable Z-force required.

A key requirement for the apparatus used in the two-step method is that the switchable vertical force must be applied in a manner that cannot significantly alter the existing in-plane alignment between the MEMS parts. Two approaches are shown as example to accomplish this.

FIG. 10 illustrates the first method wherein a plunger applies vertical force on the upper MEMS part via compressible bumpers while the device is hot and during the cooling process. At first contact between a bumper 1000 and the upper MEMS part 1005, in-plane friction is created between the plunger 1010 and the upper MEMS part 1005. As the other bumpers come into contact and the plunger 1010 continues to drop, this friction force is maintained and increased, holding the in-plane alignment fixed. Finally, the upper MEMS part 1005 comes into contact with the lower MEMS part 1015 via the passive spacers 1020 (with a force determined by the actuator driving the plunger, which is precisely controlled and limited so as not to distort the MEMS parts being joined). At this point, the device is cooled while the force is maintained. Once the solder has solidified, the assembled components can be removed from the apparatus.

The plunger, as well as the fixturing holding the lower MEMS part (the MEMS parts of the data storage device are shown as an example), must maintain their in-plane positions fixed within an acceptable tolerance, while operating in an oven or in conjunction with another apparatus that heats and cools the parts to accomplish the solder reflow and resolidification. This requires careful design to avoid in-plane motions due to thermal expansion. Furthermore, the plunger's motion needs to be constrained by a suitable bearing to allow for Z motion with little or no in-plane motion. An air bearing is an example of a bearing which can accomplish this. When in-plane tolerances are greater, ball bearings or sleeve bearings may be acceptable.

Compressible bumpers are used on the plunger to allow for a limited amount of non-coplanarity (tilt) between the plunger and the MEMS parts. Since the upper MEMS part should be bonded in a plane determined by the lower MEMS part and its spacers, and not by the plunger, the plungers allow the system to accommodate a small amount of non-coplanarity of the plunger face and the MEMS parts with no ill effects.

A second type of apparatus for applying a suitable Z force is shown on FIG. 11. Small, light, magnetic “weights” 1100 are placed on top of the upper MEMS part 1105, in a manner which is well centered over the solder joints, or a subset of the solder joints. Magnetic solenoids 1110 with switchable current (and therefore switchable field) are located in a manner below the parts being joined, such that they are well-centered under each magnetic weight. If these solenoids and weights have well-behaved fields (and no other ferromagnetic structures are present which would distort the fields from the solenoids), then the force on each magnetic weight is purely vertical (has no in-plane component) to within a given tolerance.

When the field in the solenoids is switched on, the magnetic weights produce a vertical force on the upper MEMS part 1105, driving the part against the passive spacers 1115 to establish the final spacing. The amount of force is determined by the size and magnetic permeability of the magnetic weights, and the design of and current applied to the solenoids.

Since this magnetic apparatus does not introduce in-plane friction to hold the MEMS parts in a fixed in-plane alignment during the Z compression, it is necessary that the motion proceed quickly enough (and without stray in-plane forces) to prevent the in-plane alignment from shifting beyond a given tolerance. Once the compression process begins, the self-aligning tendency (in-plane) of the solder pads may be upset. The speed with which the descent of the upper part must occur (to drive the upper part into contact with the spacers, whose in-plane friction fixes the in-plane alignment) is governed in part by the mass of the upper part and magnetic weights, whose inertia limits the amount of in-plane motion occurring relative to the in-plane disturbances present. Some trial and error is likely needed to optimize the parameters of the system to guarantee that in-plane alignment tolerances are met.

The magnetic weights are placed by robotics or other means prior to the start of the reflow process. A single lightweight structure with magnetic inclusions at the proper locations can simplify the placement of the magnetic components. Gravity should be sufficient in most cases to hold the magnetic weights in the proper locations. After cooling, the magnetic weights can be lifted off the bonded stack.

Placement of the magnetic masses may also be aided by providing grooves or other alignment feature in the top of the upper MEMS part. If cone-shaped, cylindrical, or square depressions are provided in the upper MEMS part, steel balls (which are widely available at low cost with precisely controlled dimensions) may be used as the magnetic weights.

Since the plunger apparatus provides in-plane friction to hold the in-plane alignment of the MEMS parts during the Z-compression process, it is considered a lower-risk method, and is therefore designated as the preferred embodiment. The magnetic apparatus is an alternative which may be attractive in applications where space is constrained or in-plane tolerances are not as stringent.

The vertical force exerted on the upper MEMS part, driving the MEMS part against the passive spacers to establish the final spacing, may be controlled by using electrically conductive material for spacers and adapted pads and circuitry. FIG. 12 depicts two examples of devices allowing to determine when the position wherein the vertical force exerted on the upper MEMS part can be reduced by measuring a resistance R, is reached. Therefore, when the resistance value changes e.g., to a value close to zero, it means that the distance between MEMS parts is reached and thus, the exerted vertical force can be reduced.

Naturally, in order to satisfy local and specific requirements, a person skilled in the art may apply to the solution described above many modifications and alterations all of which, however, are included within the scope of protection of the invention as defined by the following claims.

1. A method for precisely aligning at least two parts of an electronic device, each part of said electronic device comprising at least three pads, each one of said at least three pads of a first of said at least two parts being aligned with one of said at least three pads of a second of said at least two parts when said first and second parts are aligned, forming at least three pairs of pads, said method comprising the steps of:
deposing glue on said at least three pads of a first part of said at least two parts,
aligning approximately said second part to said first part, and,
lying said second part on said first part.

2. The method of claim 1 further comprising the step of reducing said glue to a liquid state.

3. The method of claim 2 wherein the pads of at least one of said at least three pairs of pads are of different sizes.

4. The method of claim 3 wherein the shape of the pads of at least one of said at least three pads is rectangular.

5. The method of claim 4 wherein the shape of the pads of at least one of said at least three pairs of pads are rectangular and wherein the angle formed by their longer edges is approximately equal to 90°.

6. The method of claim 5 wherein the shape of the pads of at least one of said at least three pairs of pads is annular.

7. The method of claim 1 wherein the shapes of the pads of a same pair of pads are similar.

8. The method of claim 1 wherein at least one of said at least two parts further comprises at least one passive stopper.

9. The method of claim 8 wherein at least one of said at least two parts further comprises three non-colinear passive stoppers.

10. The method claim 1 wherein said glue is electrically conductive.

11. The method of claim 1 wherein said glue is made of soldering alloy.

12. The method of claim 1 wherein the volume of said liquid glue is predetermined according to the shapes of the pads of said at least one pair of pads.

13. The method of claim 1 wherein the volume of said liquid glue is predetermined according to the distance that must be set between said first and second parts.

14. The method of claim 1 further comprising the step of applying a mechanical force on one of said first and second parts, said force being approximately orthogonal to the pads of said at least one pair of pads.

15. The method of claim 1 further comprising the step of hardening said liquid glue.

16. The method of claim 15 wherein said step of hardening said glue comprises a cooling step.
